(19) United States
(12) Patent Application Publication
(10) Pub. No.: US 2010/0252427 A1
(43) Pub. Date: Oct. 7, 2010

(54) MAGNETRON SPUTTERING TARGET AND MAGNETRON SPUTTERING SYSTEM

(75) Inventor: SHAO-KAI PEI, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/753,123

(22) Filed: Apr. 2, 2010

(30) Foreign Application Priority Data
Apr. 3, 2009 (CN) 200910301344.5

(51) Int. Cl. C23C 14/35

(52) U.S. Cl. 204/298.19

(57) ABSTRACT

A magnetron sputtering target comprises a magnetron device and a target positioned in a magnetic field of the magnetron device. The magnetron device comprises a metal plate, a plurality of first magnets and second magnets. A direction of the magnetic lines of the first magnets is opposite to that of the second magnets. The first magnets and the second magnets are embedded in the metal plate and arranged in a number of rows and columns. At least one first magnet is adjacent to a second magnet in one row, and at least one first magnet is adjacent to a second magnet in one column, therefore, there are magnetic lines in row direction and column direction exist in the magnetic field of the magnetron device.

### BACKGROUND

1. Technical Field

The present disclosure relates to magnetron sputtering devices, but more particularly, to a magnetron sputtering target and a magnetron sputtering system.

2. Description of Related Art

To increase the sputtering rate, a magnetron sputtering device uses the boundaries of magnetic fields to extend the trajectory of a electron, thereby changing the movement direction of the electron, therefore increasing ionization rate of the inert gases and making the best use of the energy of the electron.

However, the field of a target bombardment is not uniformly affected by density and the inequality of the magnetic lines of the magnet of a target, thereby making part of the target seriously corrode, which results in the utilization rate of target being reduced.

### BRIEF DESCRIPTION OF THE DRAWINGS

The components in the drawings are not necessarily drawn to scale, the emphasis instead being placed upon clearly illustrating the principles of the magnetron sputtering target and magnetron sputtering system. Moreover, in the drawings, like reference numerals designate corresponding parts throughout the several views.

FIG. 1 is an isometric view of a magnetron sputtering target in accordance with a first exemplary embodiment.

FIG. 2 is an exploded view of a magnetron sputtering target in accordance with the FIG. 1.

FIG. 3 is a cross-sectional view of the sputtering target of FIG. 1, taken along the line III-III in accordance with the FIG. 1.

FIG. 4 is a schematic diagram of a magnetron device for the magnetron sputtering target of FIG. 1.

FIG. 5 an isometric view of a magnetron sputtering target in accordance with a second exemplary embodiment.

FIG. 6 is a schematic diagram of a magnetron device for the magnetron sputtering target of FIG. 5.

FIG. 7 is a schematic diagram of a magnetron sputtering system in accordance with an exemplary embodiment.

### DETAILED DESCRIPTION

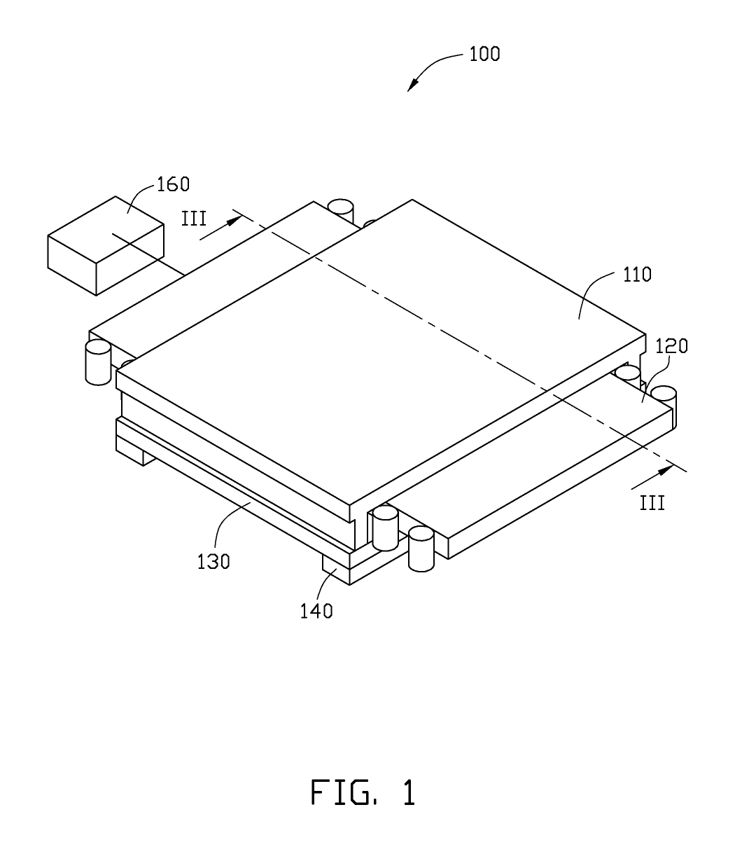

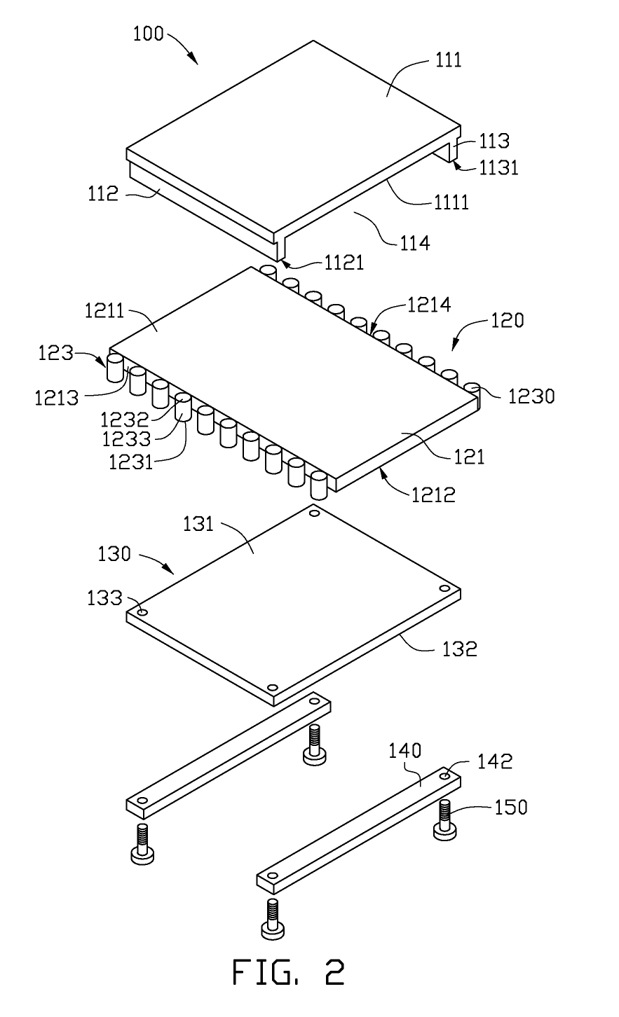

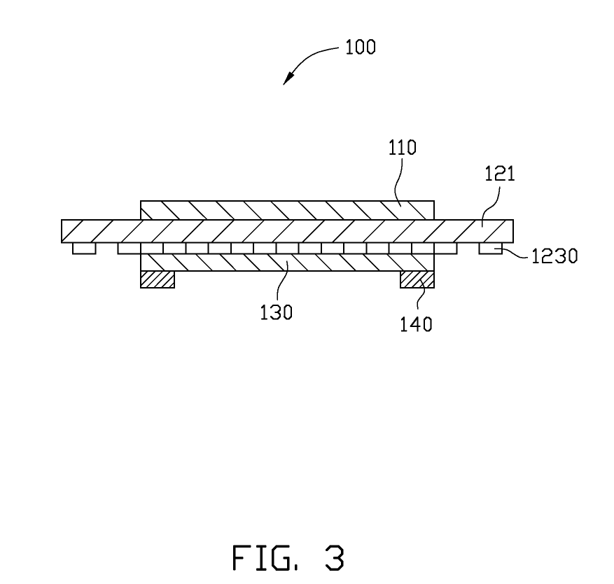

Referring to FIGS. 1-3, in a first exemplary embodiment, a magnetron sputtering target 100 includes a receiving base 110, a magnetron device 120, a target 130, two fixed plates 140, four fixed members 150 and a driving device 160.

The receiving base 110 receives the magnetron device 120 and fixes the target 130. The receiving base 110 includes a plate 111, a first wall 112 and a second wall 113 protruding from the plate 111. In the exemplary embodiment, the plate 111 is substantially rectangular and has a receiving surface 1111. The first protruding wall 112 and the second protruding wall 113 are defined in the receiving surface 1111 and extend along the lengthwise direction of the plate 111. The first protruding wall 112, the second protruding wall 113 and the receiving surface 1111 form a receiving space. Distance between the first protruding wall 112 and the second protruding wall 113 matches width of the magnetron device 120. Height of the first protruding wall 112 and the second protruding wall 113 matches height of the magnetron device 120. The first wall 112 includes a first top surface 1121 substantially parallel to the receiving surface 1111. A fitting hole (not shown) is formed in the first top surface 1121 extending toward the first protruding wall 112. In the exemplary embodiment, the first top surface 1121 defines two fitting holes. The second protruding wall 113 includes a second top surface 1131 substantially parallel to the receiving surface 1111. The second top surface 1131 further defines two fitting holes. The inner surface of the fitting hole defines an inner thread.

The magnetron device 120 is received in the receiving space 114 of the receiving base 110. The magnetron device 120 includes a metal plate 121, a plurality of magnets 122 and a plurality of supporting members 123. The metal plate 121 is substantially rectangular. Length of the metal plate 121 exceeds length of the plate 111. Width of the metal plate 121 is less than distance between the first protruding wall 112 and the second protruding wall 113. The metal plate 121 includes a top surface 1211, a bottom surface 1212 opposite to the first surface 1211, a first sidewall 1213, and a second sidewall 1214 opposite to the first sidewall 1213. The first surface 1211 contacts the receiving surface 1111. The first sidewall 1213 is opposite to the first protruding wall 112. The second sidewall 1214 is opposite to the second protruding wall 113.

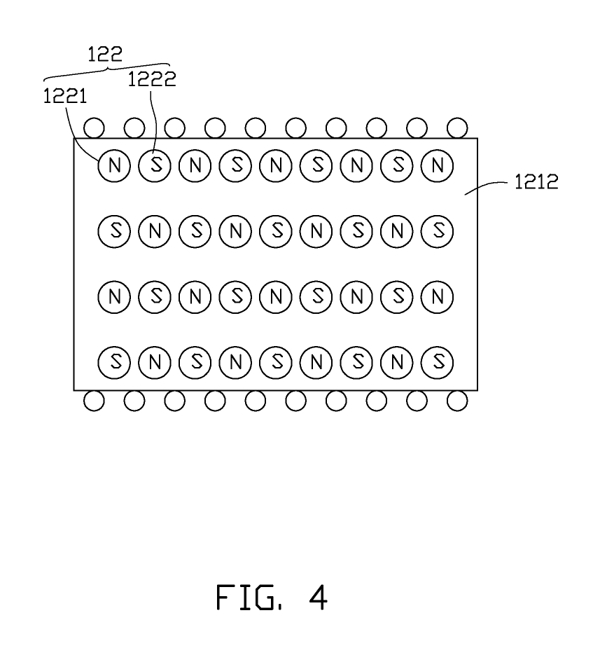

Referring to FIG. 4, an array of magnets 122 are arranged within the metal plate 121. Each magnet 122 includes a magnetic pole protruding from the second surface 1212. In the exemplary embodiment, four rows of the magnets 122 are arranged along the lengthwise direction of the metal plate 121. Each row includes nine magnets 122. The magnets 122 include a plurality of first magnets 1221 and a plurality of second magnets 1222. The direction of the magnetic lines of the first magnets 1221 and the second magnets 1222 are opposite. That is, if the N poles of the first magnets 1221 protrude from the second surface 1212, then the S poles of the second magnets 1222 protrude from the second surface 1212. The first magnets 1221 and the second magnets 1222 are arranged alternatively in both lengthwise directions and widthwise directions of the metal plate 121. The magnetic lines exist between the neighboring first magnets 1221 and the second magnets 1222. The magnetic lines produced extend along the lengthwise direction and the widthwise direction of the metal plate 121. The distance between the adjacent rows of the magnet is quite less. Then the distribution of the magnetic lines produced by a plurality of the magnets 122 is quite dense. Distances between two neighbored first and second magnets 1221 and 1222 are set to create magnetic lines with sufficient density.

In the exemplary embodiment, the supporting members 123 are rods 1230. The rods 1230 are fixed to the first sidewall 1213 and the second sidewall 1214, respectively, for supporting the metal plate 121. Height of the rods 1230 exceeds distance between the first surface 1211 and the second surface 1212. Each rod 1230 includes a supporting surface 1231, a top surface 1232, and lateral surface 1233. Each rod 1230 is fixed to the first sidewall 1213 or the second sidewall 1212 of the metal plate 121. The supporting surface 1231 protrudes from the second sidewall 1212.

Distances between the supporting surfaces 1231 and the surface 1212 are equal. In the exemplary embodiment, the distance is about 1 to 2 cm. Each rod 1230 may slidably connect to the first sidewall 1213 and the second sidewall 1214. Each rod 1230 thus may rotate between the metal plate 121 and the first protruding wall 112 and between the metal plate 121 and the second protruding wall 113. The supporting surface 1231 is in contact with the target 130. The top surface 1232 is in contact with the receiving surface 1111.

The target 130 is made of a suitable metal coating, such as Zn or Ti. In the exemplary embodiment, the target 130 is substantially rectangular. Length of the target 130 matches that of the first protruding wall 112 and the second protruding wall 113. The target 130 has a fixing surface 131 and a bombarding surface 132 which face each other. The target 130 defines four first through holes 133, which extend through the fixing surface 131 and the bombarding surface 132. The first through hole 133 is opposite to the fixing hole which is defined in the first protruding wall 112 and the second protruding wall 113.

Length of the two fixed plates 140 matches the distance between the first protruding wall 112 and the second protruding wall 113. The two fixed plates 140 define two second through holes 141 which are opposite to the first through hole 133. In the exemplary embodiment, the magnetron sputtering target 100 further includes four fixing members 150. The fixable elements 150 can be fasteners, such as bolts. The diameter of the fixable element 150 matches the aperture of the fixing hole, the first through hole 133 and the second through hole 141. The fixable element 150 extends through the second through hole 141 and the first through hole 133. The bombarding surface 132 thus contacts the two fixed plates 140. The fixing surface 131 thus contacts the first top surface 1121 and the second top surface 1131. The supporting surface 1231 is in contact with the fixing surface 131. The target 130 is thus located in the magnetic field produced by the magnetron device 120. The second surface 1212 and the fixing surface 131 are parallel to each other with a predetermined distance.

The number of the fixing portions 150 is set according to need. The driving device 160 is connected to the magnetron device 120 and drives the magnetron device 120 to move. The driving device 160 can be a pneumatic drive device, such as a pneumatic cylinder. The driving device 160 drives the magnetron device 120 to reciprocate along the extending direction of the first protruding wall 112 and the second protruding wall 113.

When sputtering the target, the driving device 160 drives the magnetron device 120 to move, the magnetic lines produced by the magnet 122 move parallel, thereby making sure the bombarding surface 132 is corroded uniformly, increasing the utilizing rate.

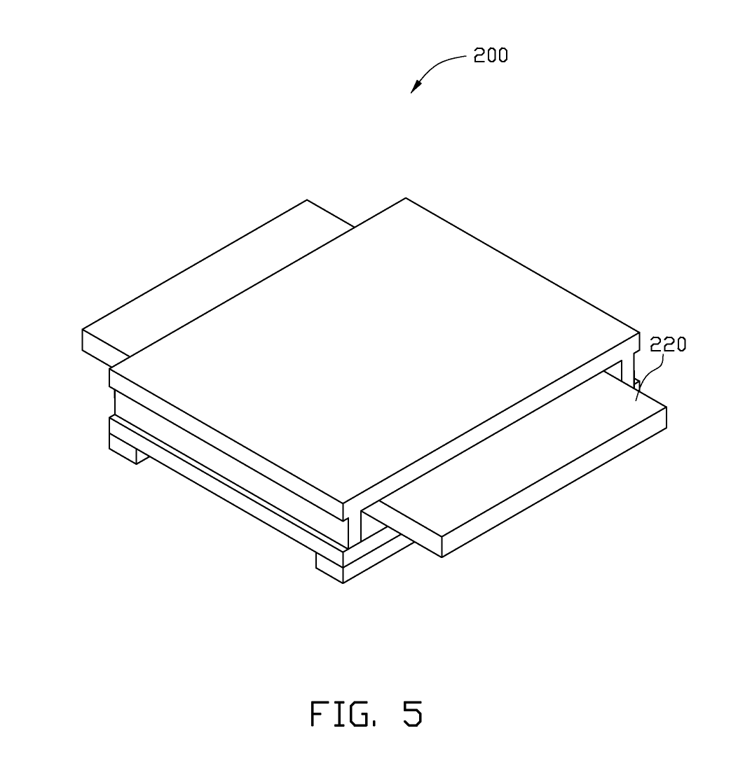

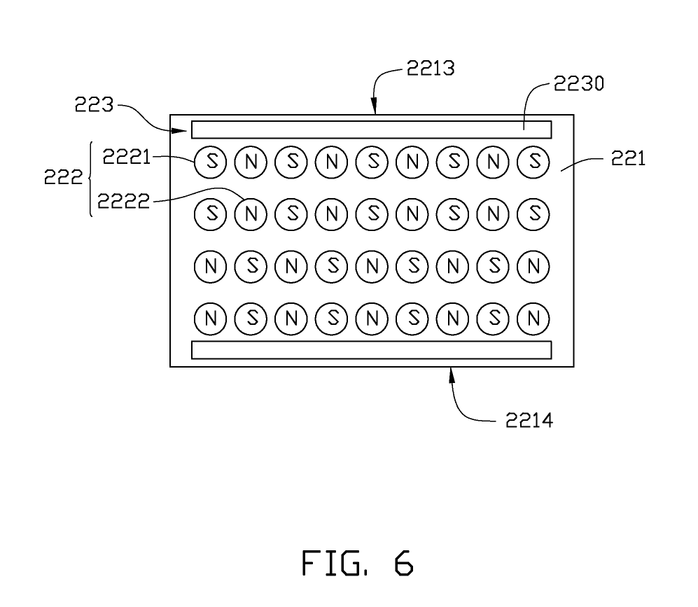

Referring to FIGS. 5 and 6, a magnetron sputtering target 200 is similar to the magnetron sputtering target 100. One difference is that the sputtering target 200 includes a plurality of magnets 222 fixed to the metal plate 221 arranged in the following way. The first magnets 2221 and the second magnets 2222 are arranged alternately along the lengthwise direction, with opposite poles protruding from surface 221. The upper two columns of magnets 2221 and 2222 are arranged in the same way, while the lower two columns of magnets 2221 and 2222 are also arranged in the same way, which is opposite to the upper two columns.

In the second exemplary embodiment, a supporting member 223 includes two supporting blocks 2230. The two supporting blocks 2230 make sure the target 130 and the magnetron device 220 are spaced from each other. The two supporting blocks 2230 are fixed to a sidewall of the second surface 2212 of the metal plate 221 adjacent to the first side plate 2213 and a sidewall of the second surface 2212 of the metal plate 221 adjacent to the second the second side plate 2214. The thicknesses of the two supporting blocks 2230 are equal. The number of the supporting blocks 2230 is set according to need.

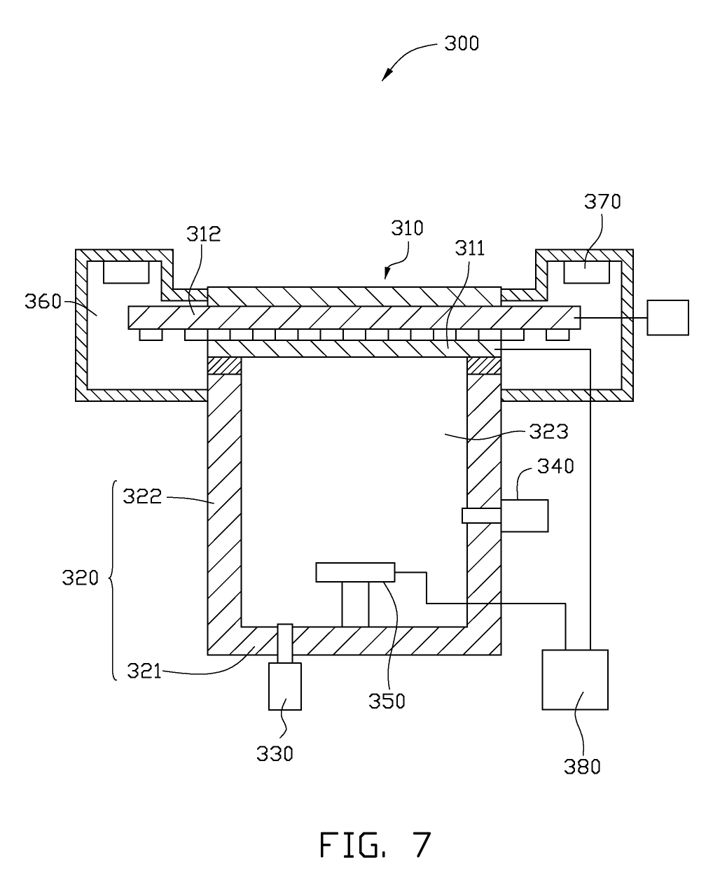

Referring to FIG. 7, a magnetron sputtering system 300 includes a magnetron sputtering target 310, a coating room 320, an evacuating device 330, an air supplying device 340, a carrying base 350, a cooling cavity 360, a cooling device 370 and a power source 380. The coating room 320 includes a bottom wall 321 and a sidewall 322. The magnetron sputtering target 310 is fixed to the sidewall 322 which causes the target 311 and the bottom wall 321 to be parallel to each other. The target 311, the sidewall 322 and the bottom wall 321 define a coating cavity 323. The carrying base 350 is fixed to the bottom wall 321 and is opposite to the magnetron sputtering target 310 for carrying coating base materials. The air supplying device 340 communicates with the coating cavity 323. The evacuating device 330 communicates with the coating cavity 323. The power source 380 is connected to the target 311 and the carrying base 350.

The cooling cavity 360 is formed around the magnetron sputtering target 310. The cooling cavity 360 communicates with the space between the metal plate 312 and the target 311. The cooling device 370 is arranged within the cooling cavity 360. The cooling device 370 can be a fan, or an air-conditioning device as example. When sputtering the target 311, the cooling device 370 injects cold air into the cooling cavity 360, thereby making the cooling cavity 360 stay at a constant temperature, and reducing the temperature of the space between the metal plate 312 and the target 311, thus avoiding the high rise in temperature of the target 311.

The magnetron device of the magnetron sputtering target 310 has different direction of the magnetic lines. The direction of the magnetic lines can move, thereby increasing the utilization ratio of the target, and reducing the sputtering cost.

Finally, while the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. A magnetron sputtering target, comprising:
a magnetron device comprising a metal plate, a plurality of first magnets and second magnets, wherein a direction of the magnetic lines of the first magnets is opposite to that of the second magnets, the first magnets and the second magnets are fixed to the metal plate and arranged in an array pattern comprising a plurality of rows and columns, at least one first magnet in each row is adjacent to a second magnet, and at least one first magnet in each column is adjacent to the second magnet, creating magnetic lines extending along the rows and columns; and
a target positioned in a magnetic field of the magnetron device.

2. The magnetron sputtering target according to claim 1, wherein a plurality of the first magnets and second magnets are alternately arranged in each row.

3. The magnetron sputtering target according to claim 1, wherein a plurality of the first magnets and second magnets are alternately arranged in each column.

4. The magnetron sputtering target according to claim 1, wherein distance between the metal plate and target is about 1 to 2 cm.

5. The magnetron sputtering target according to claim 1, wherein the magnetron device further comprises a supporting element positioned in between metal plate and target.

6. The magnetron sputtering target according to claim 1, wherein the magnetron device further comprises a supporting member located in the metal plate and extending toward orientation of the target for supporting the metal plate and spacing the metal plate and target.

7. The magnetron sputtering target according to claim 1, wherein the magnetron device further comprises a receiving base, the target is fixed in the receiving base, the magnetron device is positioned between the target and the receiving base.

8. The magnetron sputtering target according to claim 1, wherein the magnetron sputtering target further comprises a drive device, the drive device is connected to the magnetron device for driving the magnetron device to move relative to the target.

9. A magnetron sputtering system comprises a coating room, a carrying base and the magnetron sputtering target according to claim 1 to 9, wherein the magnetron sputtering target is fixed in the coating room and a coating cavity of the magnetron sputtering target is surrounded by the target and the coating room, the carrying base is received in the coating cavity in alignment with the target, the carrying base supports the coating substrate.

10. The magnetron sputtering system according to claim 10, wherein the magnetron sputtering system further comprises a cooling cavity and a cooling device, the cooling cavity is fitted around the magnetron sputtering target, the cooling device is fitted in the cooling cavity for producing cooling air, thereby reducing the temperature of the target.
